(19) United States
(12) Patent Application Publication
(10) Pub. No.: US 2016/0056034 A1
(43) Pub. Date: Feb. 25, 2016

(54) METHOD FOR MANUFACTURING A WAFER

(71) Applicants: Sino-American Silicon Products Inc., Hsinchu City (TW); GlobalWafers Co., Ltd., Hsinchu City (TW)

(72) Inventors: Jer-Liang YEH, Hsinchu City (TW); Chih-Yuan CHUANG, Hsinchu City (TW); Chun-I FAN, Hsinchu City (TW); Wen-Ching HSU, Hsinchu City (TW)

(73) Assignees: SINO-AMERICAN SILICON PRODUCTS INC., Hsinchu City (TW); GLOBALWAFERS CO., LTD., Hsinchu City (TW)

(21) Appl. No.: 14/731,902

(22) Filed: Jun. 5, 2015

(30) Foreign Application Priority Data
Aug. 22, 2014 (TW) 103129109

(51) Int. Cl. H01L 21/02

(52) U.S. Cl. CPC H01L 21/02052

(57) ABSTRACT

A method for manufacturing a wafer includes forming a plurality nano-pillars on a surface of a brick; forming a cover layer on the surfaces of the brick, wherein the cover layer covers the nano-pillars; forming an adhesive layer on the surface of the cover layer; cutting the brick into a plurality of wafers; and removing the cover layer and the adhesive layer on the wafers by a solvent, wherein the solvent reacts with the cover layer but not reacts with the brick.

### CROSS-REFERENCES TO RELATED APPLICATIONS

This non-provisional application claims priority under 35 U.S.C. §119(a) on Patent Application No. 103129109 filed in Taiwan, R.O.C. on 2014 Aug. 22, the entire contents of which are hereby incorporated by reference.

### BACKGROUND

1. Technical Field

The instant disclosure relates to the manufacturing process of wafer, in particular, to the manufacturing process of cutting the brick into the wafer.

2. Related Art

The wafer is formed by cutting the brick. During the brick cutting procedure, the wafer is likely broken or damaged if the stress concentrates. Taking polysilicon solar wafers as an example, if stress concentration happens during the cutting procedure, the polysilicon solar wafers may be broken. Although the broken wafers can be recycled, however, the production cost will be increased substantially.

We can understand that if the superficial area increases, the stress can be dispersed efficaciously. With the development of nanotechnology, nano-pillars are formed on the surface of the bricks to increase overall superficial area of bricks before the brick cutting procedure. The nano-pillars formed on the surface of the brick could disperse stress and increase yield rate. In general, the surface of the brick will then be applied with an adhesive agent to fix the brick on the cutting machine. The adhesive agent applied on the nano-pillars causes side effect. Specifically, when the nano-pillars are not formed on the surface of the brick, the adhesive agent applied on the wafer can be removed by the lactic acid or the sulphuric acid after the cutting process. However, as for the bricks with the nano-pillars, because the nano-pillars increase the overall superficial area of the brick, the bonding force between the adhesive agent and the wafer increases as well. In such situation, the adhesive agent still could not be removed effectively even by increasing the immersing time and the flushing time. In this case, operators' external force is required to brush the remained adhesive agent out of the wafers. Nevertheless, since the thickness of the wafer is relatively thin, the broken rate of the wafers still cannot be reduced.

In order to prevent the wafer from damage caused by operators during brushing procedure, methods to remove the adhesive agent are developed. For example, in China Patent Publication No. CN102610496A, the halogen gas is used to react with the adhesive agent to remove the agent. In Chinese Patent No. CN102298276B, the mixture of water and liquid CO₂ is used to remove the adhesive agent. In Chinese Patent No. CN102303868B, the wafers with the adhesive agent are placed in a furnace with around 750 degrees Celsius to ash the adhesive agent. However, although the above-mentioned methods could roughly remove the adhesive agent from the surface of wafers, portions of the adhesive agent or adhesive ashes still remains on the surface of the brick after actual implementation of the methods. In addition, the halogen gas used in the adhesive-removing procedure may induce concerns about leakage of toxic gas (halogen gas) and precautionary measures should be conducted. The high temperature during adhesive-ashing procedure may cause metallic elements on the wafers substantially diffusing, such that the electrical properties of the wafers are changed and do not conform to specification. Therefore, a method to solve the above problem is needed.

### SUMMARY

The purpose of present disclosure is providing a method for manufacturing a wafer. In one embodiment, the method for manufacturing a wafer includes forming a plurality nano-pillars on a surface of a brick; forming a cover layer on the surfaces of the brick, wherein the cover layer covers the nano-pillars; forming an adhesive layer on the surface of the cover layer; cutting the brick into a plurality of wafers; and removing the cover layer and the adhesive layer on the wafers by a solvent, wherein the solvent only reacts with the cover layer but not with the brick.

The method comprises forming the cover layer to cover on the surfaces of the brick and then forming an adhesive layer to fix the brick on the cutting machine. Thereby, during the processing procedure of cutting the brick, the stress can be dispersed through the nano-pillars so as to avoid the wafer from being broken. Due to the cover layer can be removed by chemical method (solvent), the problem that the adhesive agent retains on the surface of the wafers caused by the nano-pillars can be solved. In addition, since the method for manufacturing the wafer can be implemented in low-temperature environment without usage of toxic gas, the problems of concerns about leakage of toxic gas and diffusion of metallic elements are eliminated.

### BRIEF DESCRIPTION OF THE DRAWINGS

FIG. 1 is a flow chart illustrating a method for manufacturing a wafer according to one embodiment of the instant disclosure.

FIGS. 2-6 are cross-sectional views each illustrating a step of a method for manufacturing a wafer according to one embodiment of the instant disclosure.

### DETAILED DESCRIPTION

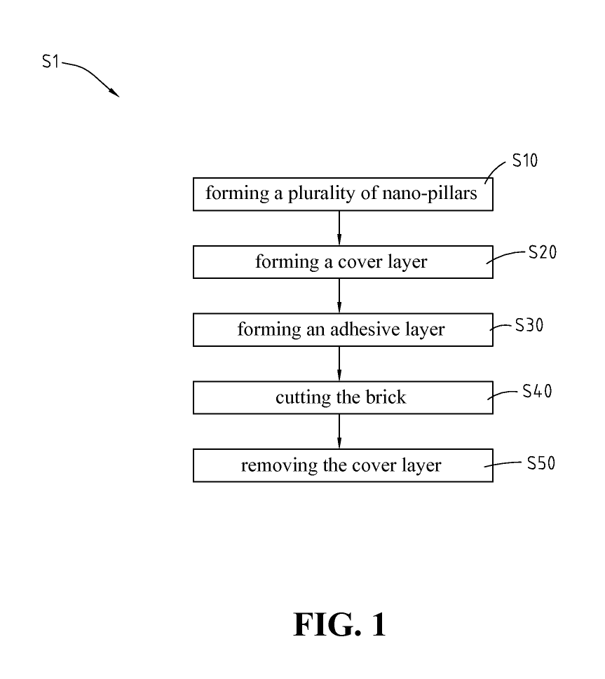

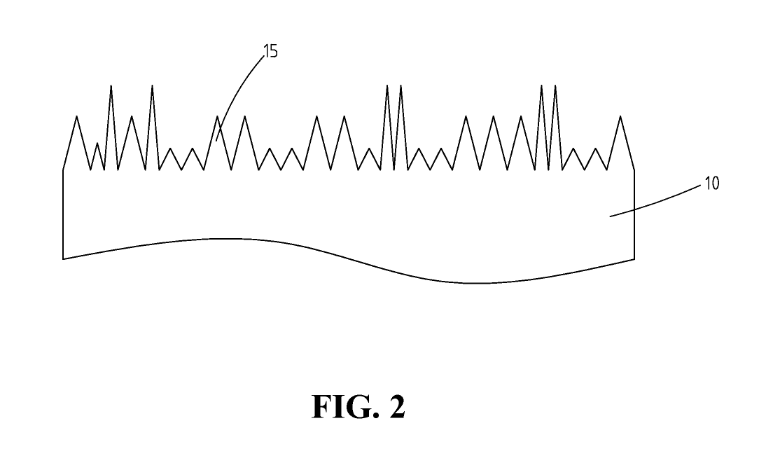

Please refer to FIGS. 1-6. FIG. 1 is a flow chart illustrating method for manufacturing a wafer according to one embodiment of the instant disclosure. FIGS. 2-6 are cross-sectional views each illustrating a step of a method for manufacturing a wafer according to one embodiment of the instant disclosure. As shown in FIG. 1, the method S1 for manufacturing a wafer includes step 510, step S20, step S30, step S40, and step S50. Each step will be illustrated hereinafter accompanying with FIGS. 2-6.

The step S10 is forming a plurality of nano-pillars. As shown in FIG. 2, the step S10 is forming the plurality of nano-pillars 15 on a surface of a brick 10. The brick 10 may be, but not limited to, silicon (cylindrical) ingot, sapphire crystal ingot, and so on. The manufacturing process of forming the nano-pillars 15 may be, but not limited to, chemical etching process or chemical vapor deposition process. The manufacturing processes are merely provided for reference, without any intention to be used for limiting the instant disclosure. The width of the nano-pillars 15 maybe between 10 to 600 nm, or specifically between 40 to 400 nm The length of the nano-pillars maybe between 1 to 15 μm, specifically between 4 to 10 μm, or even specifically around 8 μm.

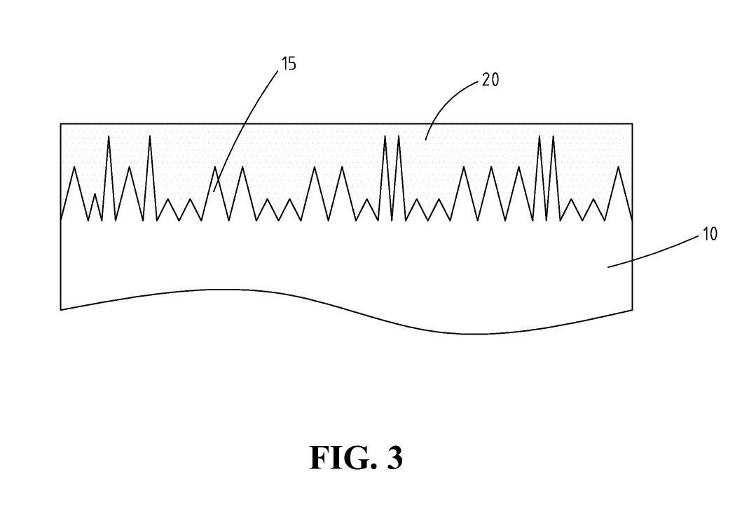

The step S20 is forming a cover layer. As shown in FIG. 3, the step S20 is forming the cover layer 20 on the surfaces of the brick 10 and the nano-pillars 15. The cover layer 20 covers the nano-pillars 15. The cover layer 20 may be an oxide layer or a nitride layer. The manufacturing process for forming the cover layer 20 maybe chemical reaction method, vapor reaction method, vapor deposition method, sol-gel method, deposition method, sputtering method, or liquid phase deposition (LPD). In one embodiment, the cover layer 20 may be silicon dioxide (SiO₂), or silicon nitride (Si₃N₄), formed by placing the brick 10 into a chamber, passing a high concentration oxygen gas or high concentration nitrogen gas into the chamber, and then heat the chamber including the high concentration gas and the brick. In one embodiment, the cover layer 20 may be silicon dioxide (SiO₂) formed by placing the brick 10 into a chamber, passing an oxidizing gas into the chamber, and then heat the chamber including the oxidizing gas and the brick. The oxidizing gas maybe an oxygen gas, silane (SiH₄), or mixture of the oxygen gas and silane. In one embodiment, the cover layer 20 may be a silicon dioxide (SiO₂) layer formed by applying tetraethyl orthosilicate (TEOS) on the surface of the brick 10, placing the brick 10 into a chamber, and heating the chamber including the brick. The manufacturing process of forming the cover layer 20 as described above is only intended as an example and is not limit to the scope of the present disclosure.

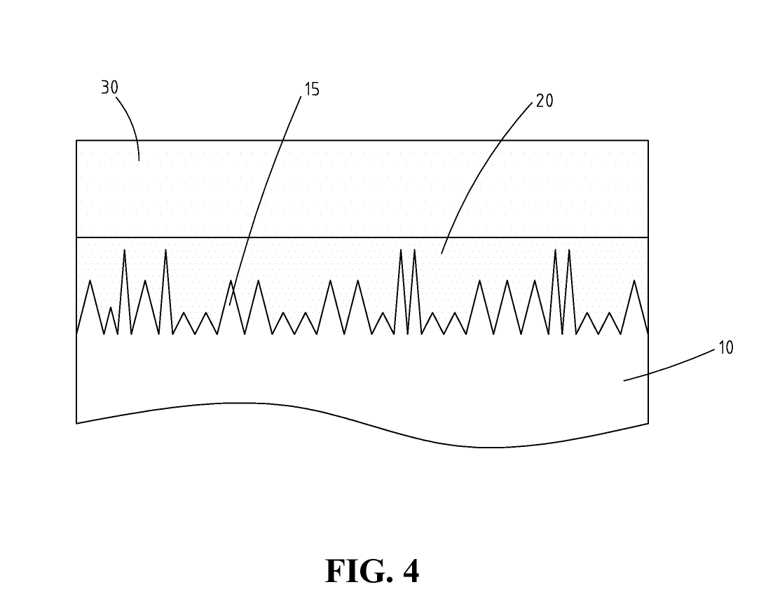

The step S30 is forming an adhesive layer. As shown in FIG. 4, the step S30 is forming the adhesive layer 30 on the surface of the cover layer 20 to facilitate the subsequent step of fixing the brick 10 on the cutting machine. The manufacturing process of forming the adhesive layer 30 may be roll-coating method, dispensing method, or spin-coating method. The manufacturing process of forming the adhesive layer 30 as described above is only intended as an example and is not limit to the scope of the present disclosure.

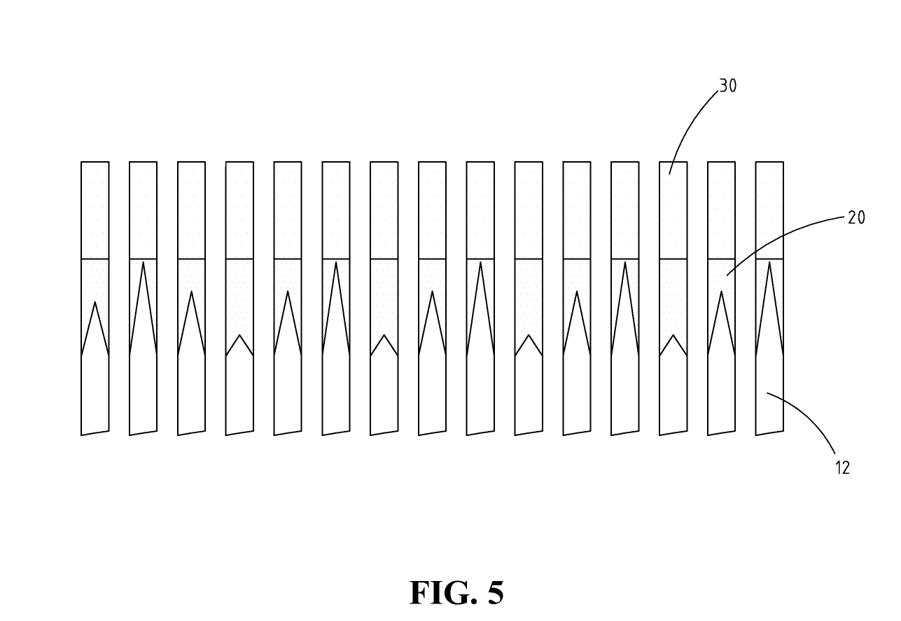

The step S40 is cutting the brick. As shown in FIG. 5, the brick 10 produced after the steps S10, S20, S30, S40 is cut into a plurality of wafers 12. At the moment, each wafer 12 still has part of the cover layer 20 and the adhesive layer 30.

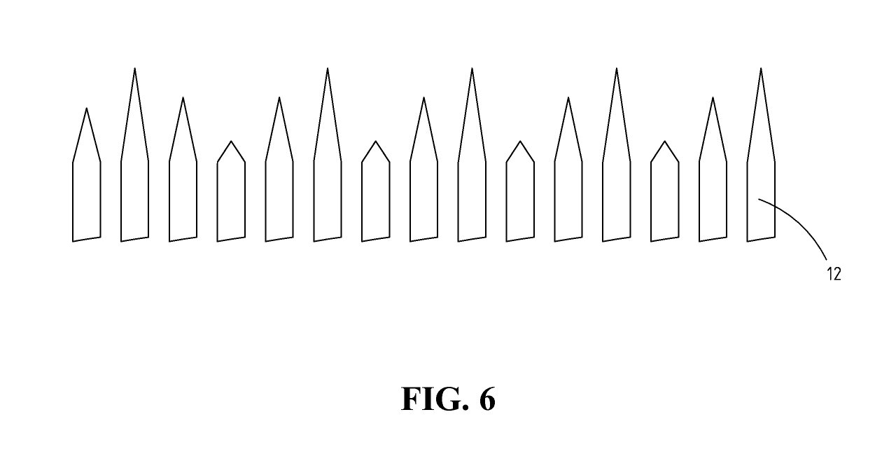

The step S50 is removing the cover layer 20 by a solvent. Once the cover layer 20 is removed, the adhesive layer 30 is removed as well. FIG. 6 illustrates the wafers after the cover-layer-removing procedure is finished. The solvent maybe any solvent which does not react with the wafers 12 but reacts with the cover layer 20. In one embodiment, the cover layer 20 may be silicon dioxide (SiO₂) and the solvent may be hydrogen fluoride (HF). In one embodiment, the cover layer 20 may be a silicon nitride (Si₃N₄) layer and the solvent may be phosphoric acid (H₃PO₄). The manufacturing process of removing the cover layer 20 as described above is only intended as an example and is not limit to the scope of the present disclosure. The reaction between the solvent and the cover layer 20 may be, but not limited to, chemical reactions like, but not limited to, etching, or dissolving. The non-reaction between the solvent and the wafers/bricks means there is no chemical reaction between the solvent and the brick.

The steps S10, S20, S30, S40 may be implemented at a temperature around 0 to 200 , specifically at temperature between 70-150. Consequently, the diffusion of metallic elements of the brick 10 or the wafers 12 can be effectively controlled. Therefore, the electrical properties of the wafers 12 can be maintained.

The method for manufacturing a wafer comprises forming the cover layer to cover on the surfaces of both the nano-pillars and the brick. During the processing procedure of cutting the brick, the stress can be dispersed due to the increased superficial area obtained by the nano-pillars so as to prevent the wafers from being broken. Owing that the cover layer can be removed by chemical method, the problem that the adhesive layer retains on the surface of the wafers caused by the nano-pillars can be solved. In addition, since the method for manufacturing the wafer can be implemented in low-temperature environment without usage of toxic gas, the problems of concerns about leakage of toxic gas and diffusion of metallic elements are eliminated.

While the instant disclosure has been described by the way of embodiments and in terms of the preferred embodiments, it is to be understood that the invention needs not be limited to the disclosed embodiments. For anyone skilled in the art, various modifications and improvements within the spirit of the instant disclosure are covered under the scope of the instant disclosure. The covered scope of the instant disclosure is based on the appended claims.

What is claimed is:

1. A method for manufacturing a wafer, comprising:
forming a plurality nano-pillars on a surface of a brick;
forming a cover layer on the surfaces of the brick, wherein the cover layer covers the nano-pillars;
forming an adhesive layer on the surface of the cover layer;
cutting the brick into a plurality of wafers; and
removing the cover layer and the adhesive layer on the wafers by a solvent,
wherein the solvent reacts with the cover layer but not reacts with the brick.

2. The method for manufacturing a wafer of claim 1, wherein the cover layer is an oxide layer or a nitride layer.

3. The method for manufacturing a wafer of claim 2, wherein the step of removing the cover layer is proceeded at 0 to 200° C.

4. The method for manufacturing a wafer of claim 3, wherein the cover layer is silicon dioxide (SiO₂), and the solvent is hydrogen fluoride (HF).

5. The method for manufacturing a wafer of claim 4, wherein the cover layer is formed by applying tetraethyl orthosilicate on the surface of the brick, placing the brick into a chamber and heating the chamber including the brick.

6. The method for manufacturing a wafer of claim 4, wherein the cover layer is formed by placing the brick into a chamber, passing an oxidizing gas into the chamber and heating the chamber including the brick and the oxidizing gas, wherein the oxidizing gas is oxygen gas, silane, or mixture of the oxygen gas and silane.

7. The method for manufacturing a wafer of claim 3, wherein the cover layer is silicon nitride (Si₃N₄), and the solvent is phosphoric acid (H₃PO₄).

8. The method for manufacturing a wafer of claim 2, wherein the forming the cover layer is forming the cover layer by a chemical reaction method, a vapor reaction method, a vapor deposition method, a sol-gel method, a deposition method, a sputtering method, or a liquid phase deposition.

9. The method for manufacturing a wafer of claim 1, wherein the length of the nano-pillars is between 1 to 15 μm.

10. The method for manufacturing a wafer of claim 9, wherein the length of the nano-pillars is between 4 to 10 μm.
